(19) United States
(12) Patent Application Publication
(10) Pub. No.: US 2024/0405690 A1
(43) Pub. Date: Dec. 5, 2024

(54) PULSE INVERTER AND POWER MODULE FOR SUCH A PULSE INVERTER

(71) Applicants: Volkswagen Aktiengesellschaft, Wolfsburg (DE); AUDI Aktiengesellschaft, Ingolstadt (DE)

(72) Inventors: Jan ZACHARIAE, Braunschweig (DE); Holger AMECKE, Braunschweig (DE); Viktor MAZNOV, Eschenstruth (DE); Daniel RUPPERT, Lenting (DE)

(73) Assignees: Volkswagen Aktiengesellschaft, Wolfsburg (DE); AUDI Aktiengesellschaft, Ingolstadt (DE)

(21) Appl. No.: 18/731,825

(22) Filed: Jun. 3, 2024

(30) Foreign Application Priority Data
Jun. 1, 2023 (DE) 10 2023 114 477.4

(51) Int. Cl. H02M 7/00; B60L 15/08

(52) U.S. Cl. CPC H02M 7/003; B60L 15/08

(57) ABSTRACT

A pulse inverter and to a power module for such a pulse inverter. The power module has a hard encapsulation body in which the power module lug is embedded, which can be connected in a lap weld to a lug leading to a DC link capacitor. The power module lug is supported on its side, opposite the lug, on a load-bearing hard encapsulation material of the hard encapsulation body, which material acts as a counterholder in the welding process.

This nonprovisional application claims priority under 35 U.S.C. § 119(a) to German Patent Application No. 10 2023 114 477.4, which was filed in Germany on Jun. 1, 2023, and which is herein incorporated by reference.

### BACKGROUND OF THE INVENTION

### Field of the Invention

The invention relates to a pulse inverter for a drive unit of an electrically powered vehicle and to a power module for such a pulse inverter.

### Description of the Background Art

The electric drive unit of an electrically powered vehicle has a pulse inverter whose power modules are connected with their DC connections to a DC link capacitor and are connected with their AC connections to the electric motor of the drive unit via an AC current bridge.

A generic pulse inverter is constructed from a mounting support to which the DC link capacitor and at least one power module are attached, which are connected in a lap weld with their contact lugs. The power module is designed with a hard encapsulation body in which the power module lug is embedded. A pulse inverter constructed in this way can be manufactured using the following process steps: First, the DC link capacitor and the power module are premounted on the mounting support in a premounting step. A welding step then follows in which the overlapping contact lugs can be pressed onto a counterholder using a hold-down device with the formation of a zero gap and can then be welded together.

In the state of the art, the welding tool required for this has a separate counterholder which has complicated components and on which the two contact lugs of the DC link capacitor and power module to be welded are supported.

An electronic device for an electric powertrain of a vehicle is known from US 2017/0033704 A1. The device comprises a power module assembly having a housing, defining a first side, and an array of power modules disposed within the housing. Each power module comprises first electrical contact surfaces at least partially embedded in the first side and having an attachment surface substantially parallel to the first side. A capacitor assembly comprises a housing defining a second side, which is substantially coplanar with the first side, and an array of second electrical contact terminals at least partially embedded in the second side. The second electrical contact terminals have an attachment surface running substantially parallel to the second side. A busbar mechanically and electrically couples at least one of the first contact patches to at least one of the second contact patches.

A power module is known from US 2018/0206359 A1, which has a power substrate, a housing arranged on the power substrate, and a first terminal electrically connected to the power substrate. The first terminal comprises a contact surface located above the housing at a first elevation. The power module additionally comprises a second terminal with a contact surface located above the housing at a second elevation different from the first elevation. In addition, a third terminal is provided electrically connected to the power substrate.

### SUMMARY OF THE INVENTION

It is therefore an object of the invention to provide a pulse inverter that is easier to manufacture in terms of production technology compared to the prior art and/or has a reduced leakage inductance and sufficient clearance/creepage distances compared to the prior art.

The invention is based on a pulse inverter in which the DC link capacitor and at least one power module are attached to a mounting support. The DC link capacitor and the power module are connected to each other via contact lugs in a lap weld, which is created in a laser welding process, for example. The power module is designed with a hard encapsulation body in which the power module lug is embedded. A pulse inverter constructed in this way can be manufactured in the following process steps: First, the DC link capacitor and the power module are premounted on the mounting support in a premounting step. A welding step then follows in which the overlapping contact lugs can be pressed onto a counterholder using a hold-down device with the formation of a zero gap and can then be welded together. According to the characterizing part of claim 1, the counterholder is no longer provided as a separate component. Rather, according to the invention, the counterholder is a materially uniform and integral component of the hard encapsulation body. In the welding step, the two contact lugs can therefore be supported on the load-bearing hard encapsulation material, which acts as a counterholder.

The capacitor lug of the DC link capacitor and the power module lug can be connected directly in a lap weld. Alternatively, the capacitor lug of the DC link capacitor and the power module lug can be in electrical contact with each other by means of a connecting lug. The connecting lug is a separate sheet metal part that is connected in a lap weld to both the capacitor lug of the DC link capacitor and the power module lug.

In a technical implementation, in addition, a printed circuit board, in particular made of ceramic, with power transistors positioned thereon can be embedded in the hard encapsulation body. In this case, the power module lug can have a lug base which is in contact with a trace on the printed circuit board. The lug base can merge into a contact leg, which is formed with a terminal surface exposed by the hard encapsulation material. The terminal surface of the contact leg can be connected to the capacitor lug in the above-mentioned lap weld. An essential core of the invention is that the printed circuit board is not directly connected in a lap weld to the lug leading to the DC link capacitor, but is spaced from the lap weld-with the interposition of hard encapsulation material—whereby breakage of the printed circuit board due to mechanical and/or thermal stress can be avoided during the manufacturing process.

The printed circuit board can be a direct copper bonding substrate (DCB), for example, which is a proven standard for power electronics modules in industrial, household appliance, and automotive applications. DCBs is formed of both an Al₂O₃ substrate (aluminum oxide), which serves as an insulating layer, and copper compounds.

According to an example, both the lug base and the lug leg of the power module lug—with the exception of at least its terminal surface—can be embedded in the hard encapsulation body. In this case, the lug leg underside, facing away from the exposed terminal surface, is therefore in a direct molded connection with the load-bearing hard encapsulation material.

It is preferable if the terminal surface of the power module lug is not flush with the outer contour of the hard encapsulation body. Such a flush arrangement of the terminal surface on the outer contour of the hard encapsulation body would result in an insufficient creepage/clearance distance. Instead, due to the terminal surface set back into the hard encapsulation body, sufficient clearance/creepage distances can be provided.

The material recess can be limited by hard encapsulation side walls, which are raised from the bottom by the profile depth. In addition, the material recess in the direction of the DC link condenser can be designed without a raised hard encapsulation side wall, but rather with an access area open at the side. The capacitor lug can protrude into the material recess of the hard encapsulation body through the access area.

The printed circuit board can be embedded in a lower plane of the hard encapsulation body when viewed in the power module thickness direction, whereas the lug leg is embedded vertically offset thereto in an upper plane of the hard encapsulation body. The terminal surface of the power module lug and the printed circuit board can preferably be aligned plane-parallel to each other. With this vertically offset arrangement, the power module lug can be realized as follows: Thus, the lug leg can merge into the lug base via a transition section oriented in the thickness direction. These overlap each other by an overlap dimension when viewed in the thickness direction. In this way, the printed circuit board can extend as far as possible up to the edge of the hard encapsulation body, as a result of which the distance between the DC link capacitor and the printed circuit board and thus the leakage inductance can be reduced.

The hard encapsulation body can be formed cuboid in shape. The power module can have a plurality of power module lugs arranged on the same cuboid side of the hard encapsulation body. In this way, a plurality of power modules can be closely stacked next to each other on the remaining cuboid sides of the hard encapsulation body. Each terminal surface of the power module lugs can be assigned its own material recess in the hard encapsulation body. The material recesses can be spaced apart via hard encapsulation webs, which form the hard encapsulation side walls for delimiting the respective material recess.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIGS. 1 to 5 are each views with which a pulse inverter according to an example of the invention is described; and

FIGS. 6 to 9 are each views of the conventional art.

### DETAILED DESCRIPTION

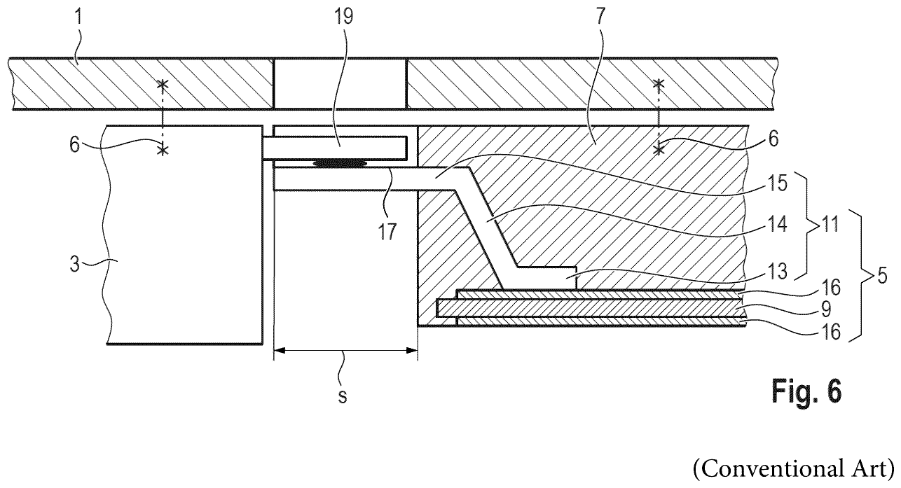

For a simpler understanding of the invention, reference is first made to the comparative example shown in FIGS. 6 to 8. A pulse inverter in the assembled state is shown in FIG. 6 to the extent necessary for understanding the invention. Accordingly, the pulse inverter has a mounting support 1 to which a DC link capacitor 3 and power modules 5 are screwed at screw positions 6. Of the three power modules, only one power module 5 is indicated in FIG. 6. Power module 5 shown in FIG. 6 is formed with a hard encapsulation body 7, in which a ceramic printed circuit board 9, a power module lug 11, and power transistors, which are positioned on circuit board 9, are embedded. Power module lug 11 is formed approximately Z-shaped in cross section with a lug base 13, a transition section 14, and a lug leg 15. Lug base 13 is in contact with a copper trace 16 of circuit board 9; in addition, lug base 13 merges into lug leg 15 via transition section 14. In FIG. 6, this leg protrudes with a projection s from a narrow side of cuboid hard encapsulation body 7.

When viewed in the power module thickness direction, circuit board 9 is embedded in a lower plane of hard encapsulation body 7, whereas lug leg 15 is embedded vertically offset in an upper plane of hard encapsulation body 7. Further, an upward-facing terminal surface 17 of lug leg 15 is exposed from the hard encapsulation, which surface is connected in a lap weld to a capacitor lug 19 of DC link capacitor 3. A cooler can be provided on the underside of power module 5, said side facing away from mounting support 1.

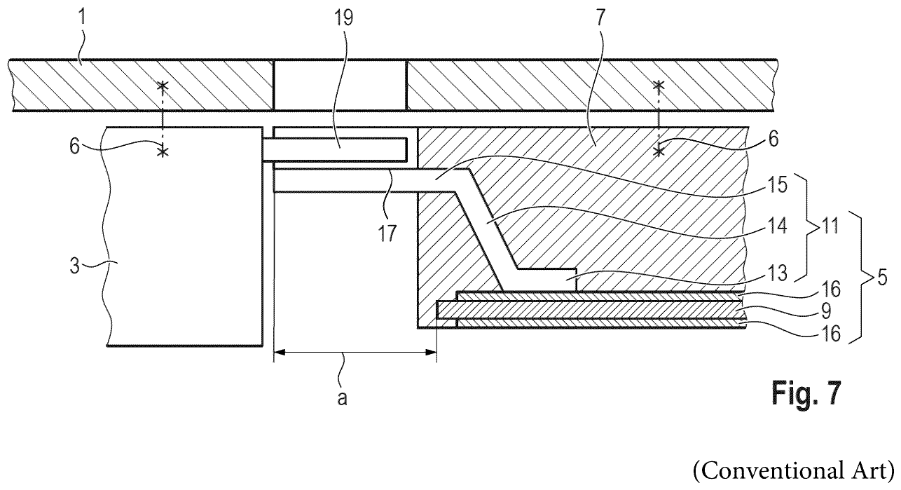

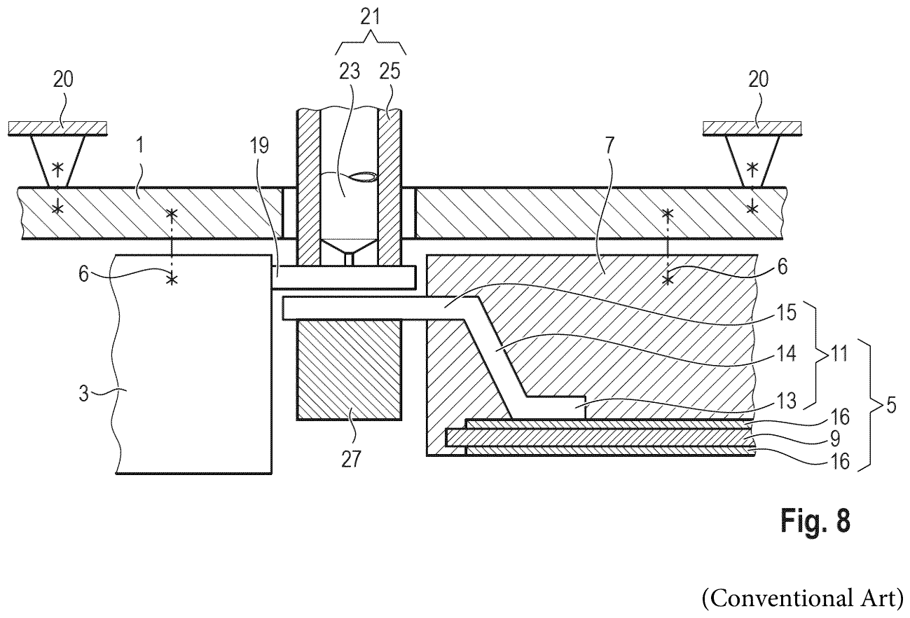

A pulse inverter constructed in this way can be manufactured in the process steps illustrated in FIGS. 7 and 8: Thus, in a premounting step (FIG. 7), DC link capacitor 3 and the power module 5 are first premounted in the correct position on mounting support 1. The premounted unit shown in FIG. 7 is then transferred to a welding station, where mounting support 1 is clamped in a fixed position at clamping points 20 (FIG. 8).

When the welding step is carried out, the two contact lugs 11, 19 can be welded together using a laser welding device 21. Laser welding device 21 is only roughly indicated schematically in FIG. 8. Accordingly, laser welding device 21 formed of a laser welding head 23 as well as a hold-down device 25 and a counterholder 27 interacting with it. During the welding step, the two overlapping lugs 11, 19 are pressed onto counterholder 27 with hold-down device 25, with the formation of a zero gap. The laser welding process then starts.

As emerges from FIGS. 6 to 8, a sufficiently large tool access for counterholder 27 must be provided between DC link capacitor 3 and power module 5. This results in a correspondingly large distance ‘a’ (FIG. 7) between DC link capacitor 3 and circuit board 9, which can generate leakage inductances. In addition, the welding process with counterholder 27, which is kept as a separate component, is complicated in terms of components.

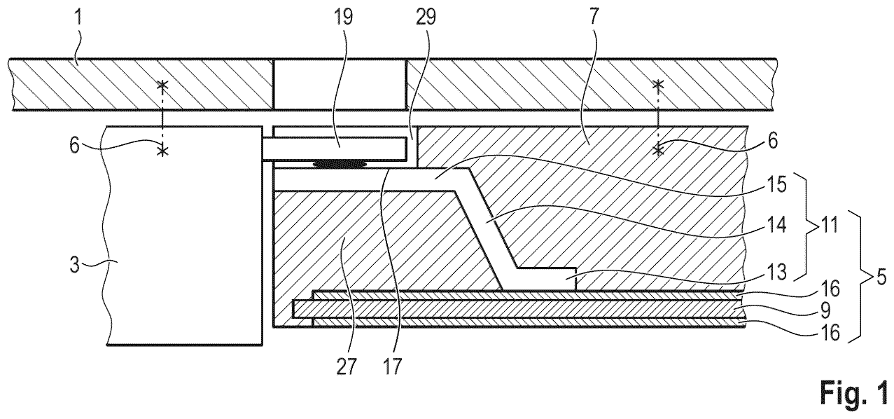

As a departure from the comparative example shown in FIGS. 6 to 8, a pulse inverter of the invention is described below with reference to FIGS. 1 to 5, which is constructed substantially in the same way as in the comparative example. Reference is therefore made to the previous description.

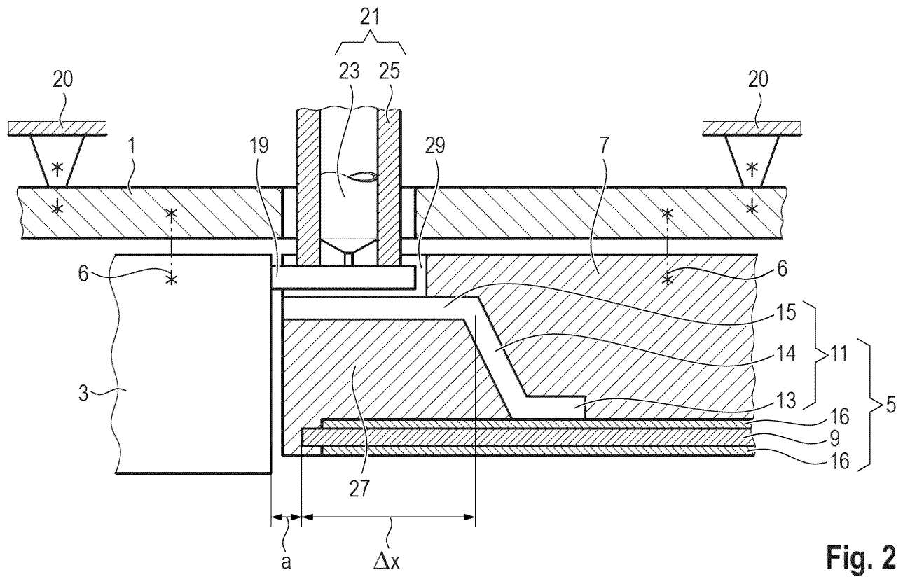

In contrast to the comparative example of FIGS. 6 to 8, according to the invention the provision of a separate counterholder 27 during the welding process is dispensed with. Instead, in FIG. 1 or 2, counterholder 27 is a materially uniform and integral component of hard encapsulation body 7. During the welding step, the two contact lugs 11, 19 are therefore supported directly on the load-bearing hard encapsulation material, which acts as a counterholder 27.

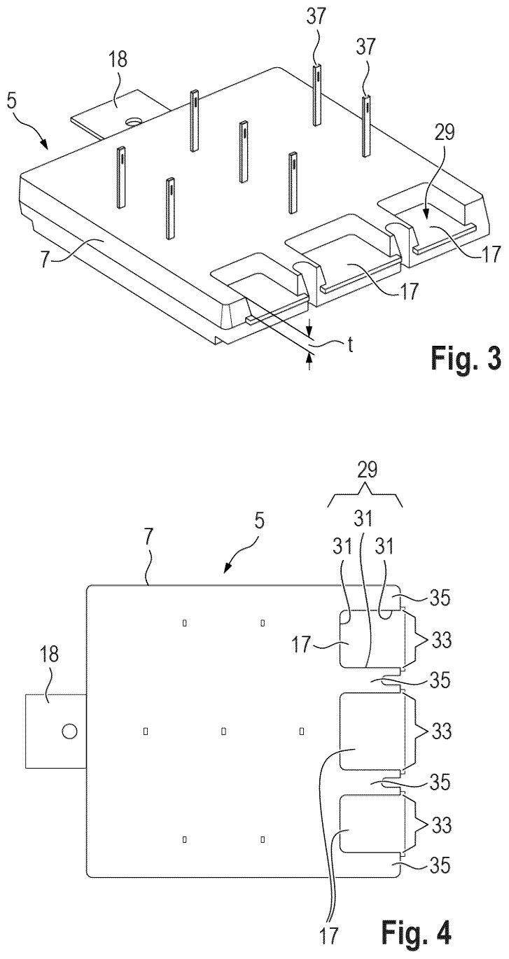

In FIG. 1 or 2, terminal surface 17 of power module lug 11 is not aligned flush with the cuboid outer contour of hard encapsulation body 7. Rather, hard encapsulation body 7 has a material recess 29, which is set back from the outer contour of hard encapsulation body 7 with a profile depth t (FIG. 3), and the bottom of which is formed by terminal surface 17. Material recess 29 is defined by hard encapsulation side walls 31 (FIG. 4), which are raised from the bottom by the profile depth t. However, material recess 29 is formed in the direction of DC link capacitor 3 without a raised hard encapsulation side wall 31, but rather with an open access area 33 (FIG. 4), through which capacitor lug 19 protrudes into material recess 29. Capacitor lug 19 can therefore be designed geometrically to be simply flat, i.e., without an angled profile, in order to contact terminal surface 17.

A power module 5 of the invention is shown by itself in FIGS. 3 and 4. Accordingly, hard encapsulation body 7 is formed cuboid in shape. In addition, power module 5 has a total of three power module lugs 11 on its DC side with terminal surfaces 17 formed thereon. These are all arranged on the same cuboid side of hard encapsulation body 7, so that a plurality of power modules 5 can be stacked closely next to each other on their cuboid sides formed at right angles thereto.

In order to provide the required clearance and creepage distances, in FIGS. 3 and 4 each terminal surface 17 of power module lugs 11 is assigned its own material recess 29 in hard encapsulation body 7. In FIG. 4, the three material recesses 29 are spaced apart via hard encapsulation webs 35. Hard encapsulation webs 35 each form hard encapsulation side walls 31, which define the respective material recess 29.

Power module 5 shown in FIG. 3 or 4 has on its AC side, opposite the DC side, an AC lug 18, which can be connected to the electric machine via an AC current bridge. In addition, signal contacts 37 protrude upwards from the top of power module 5 in the form of pins. These can be press-fitted to a control board of the pulse inverter.

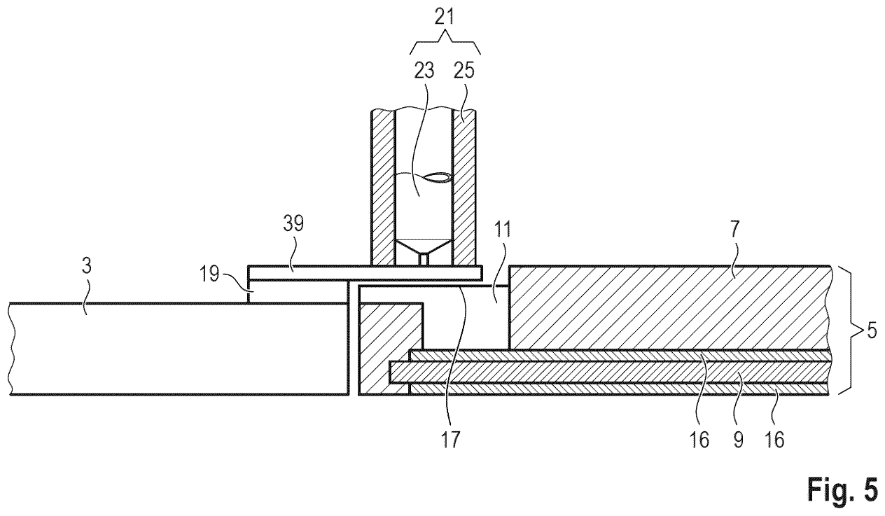

In FIGS. 1 to 5, capacitor lug 19 and power module lug 11 are connected directly in a lap weld. In contrast thereto, FIG. 5 shows a pulse inverter according to a second example, in which capacitor lug 19 of DC link capacitor 3 and power module lug 11 are in electrical contact with each other by means of a connecting lug 39. Connecting lug 39 is a separate sheet metal part which is connected in a lap weld to both capacitor lug 19 of DC link capacitor 3 and power module lug 11. According to FIG. 5, capacitor lug 19 is positioned on the upper side of DC link capacitor 3, whereby capacitor lug 19 and power module lug 11 are aligned flush in the horizontal plane.

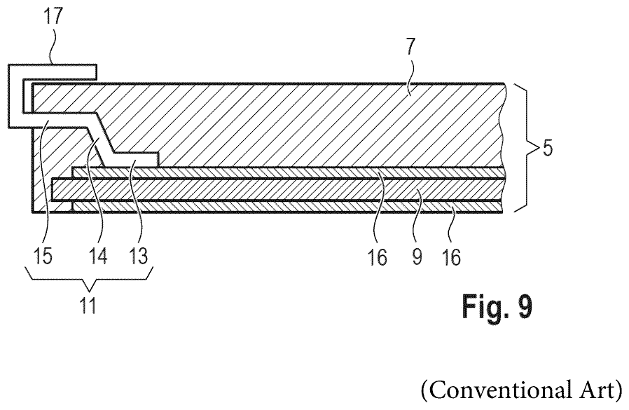

A further comparative example, not covered by the invention, is shown in FIG. 9. The comparative example shown in FIG. 9 is similar to the comparative example in FIGS. 6 to 8, namely, with the difference that power module lug 11 is bent over with its free projection s up to the top of the power module. Lug leg 15 therefore lies loosely on the top of hard encapsulation body 7. In the welding step, the two contact lugs 11, 19 are pressed onto the load-bearing hard encapsulation material of hard encapsulation body 7 by means of the hold-down device 25, which material acts as a counterholder. In contrast to the invention, in FIG. 9 lug leg 15 of the power module lug lies loosely on the outer contour of hard encapsulation body 7. In contrast, according to the invention, lug leg 15 is embedded in hard encapsulation body 7 in such a way that the underside of lug leg 15, said underside facing away from exposed terminal surface 17, is in a molded connection with the hard encapsulation material.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A pulse inverter for a drive unit of an electrically powered vehicle, comprising:
a mounting support to which a DC link capacitor and at least one power module are attached, which are in a welded joint, in particular a lap weld, via lugs, the power module comprising a hard encapsulation body in which the power module lug is embedded, the pulse inverter being manufactured in the following process steps:
a premounting step in which the DC link capacitor and the power module are premounted on the mounting support;
a welding step, in which the power module lug and a lug, overlapping therewith and leading to the DC link capacitor, are pressed onto a counterholder using a hold-down device with the formation of a zero gap, and then welded together,
wherein the counterholder is a materially uniform and integral component of the hard encapsulation body so that in the welding step the overlapping lugs are supported on the load-bearing hard encapsulation material, which acts as a counterholder.

2. The pulse inverter according to claim 1, wherein a printed circuit board made of ceramic with power transistors positioned thereon is embedded in the hard encapsulation body, and/or wherein the power module lug has a lug base which is in contact with a trace of the printed circuit board, and wherein the lug base merges into a lug leg or a transition section, and/or wherein the lug leg has a terminal surface which is exposed by the hard encapsulation material of the hard encapsulation body and is connected in a lap weld to the lug leading to the DC link capacitor, and/or wherein the lug leg with the terminal surface formed thereon is spaced from the printed circuit board so that the hold-down force does not act directly on the printed circuit board during the welding process.

3. The pulse inverter according to claim 2, wherein the lug base and the lug leg, with the exception of at least its terminal surface, are embedded in the hard encapsulation body, and wherein an underside of the lug leg, said underside facing away from the exposed terminal surface, is in a bonded molded connection with the supporting hard encapsulation material.

4. The pulse inverter according to claim 2, wherein the hard encapsulation body has a material recess set back with a profile depth from the outer contour of the hard encapsulation body, the bottom of which recess is formed by the terminal surface of the power module lug.

5. The pulse inverter according to claim 4, wherein the material recess is defined by hard encapsulation side walls, which are raised from the bottom by the profile depth.

6. The pulse inverter according to claim 5, wherein the material recess formed in the hard encapsulation body is formed in the direction of the DC link capacitor without a raised hard encapsulation side wall or with a laterally open access area through which the capacitor lug protrudes into the material recess.

7. The pulse inverter according to claim 2, wherein the printed circuit board is embedded in a lower plane of the hard encapsulation body when viewed in the power module thickness direction, and the lug leg is embedded vertically offset thereto in an upper plane of the hard encapsulation body.

8. The pulse inverter according to claim 2, wherein the terminal surface of the power module lug and the printed circuit board are aligned plane-parallel to each other, and/or wherein the power module lug is formed of the lug leg, which merges into the lug base via a transition section oriented in the thickness direction, and/or wherein, when viewed in the power module thickness direction, the lug leg, formed with the terminal surface and the printed circuit board overlap one another by an overlap dimension, whereby a distance between the DC link capacitor and the printed circuit board and thus the leakage inductance is reduced.

9. The pulse inverter according to claim 1, wherein the hard encapsulation body is formed cuboid in shape, and wherein the power module has a plurality of power module lugs which are arranged on the same cuboid side of the hard encapsulation body, and wherein each terminal surface of the power module lugs is assigned its own material recess in the hard encapsulation body, which recesses are spaced apart via hard encapsulation webs, and wherein the hard encapsulation webs form the hard encapsulation side walls.

10. A power module for a pulse inverter according to claim 1, wherein the power module has a hard encapsulation body in which at least one power module lug is embedded, which is connected in a lap weld to a lug leading to a DC link capacitor, and wherein the power module lug is supported on its side, opposite the lug, on a load-bearing hard encapsulation material of the hard encapsulation body, which material acts as a counterholder in the welding process.
